(19) United States
(12) Patent Application Publication
(10) Pub. No.: US 2024/0079946 A1
(43) Pub. Date: Mar. 7, 2024

(54) ELECTRONIC CIRCUITRY AND POWER CONVERSION DEVICE

(71) Applicant: KABUSHIKI KAISHA TOSHIBA, Tokyo (JP)

(72) Inventors: Shusuke KAWAI, Yokohama Kanagawa (JP); Takeshi UENO, Kawasaki Kanagawa (JP)

(73) Assignee: KABUSHIKI KAISHA TOSHIBA, Tokyo (JP)

(21) Appl. No.: 18/185,288

(22) Filed: Mar. 16, 2023

(30) Foreign Application Priority Data
Sep. 7, 2022 (JP) 2022-142469

(51) Int. Cl. H02M 1/00; H02M 1/44

(52) U.S. Cl. CPC H02M 1/0009; H02M 1/0067; H02M 1/44

(57) ABSTRACT

In one embodiment, electronic circuitry includes an input terminal, a detection terminal, a diode having a cathode connected to the input terminal and an anode connected to the detection terminal, a resistor connected between the detection terminal and a first reference voltage, and a capacitor connected between the detection terminal and a second reference voltage. A voltage equal to a minimum value of a voltage applied to the input terminal is outputted from the detection terminal.

### REFERENCE TO RELATED APPLICATIONS

This application is based upon and claims the benefit of priority from the prior Japanese Patent Application No. 2022-142469, filed on Sep. 7, 2022, the entire contents of which are incorporated herein by reference.

### FIELD

The present embodiment relates to electronic circuitry and a power conversion device.

### BACKGROUND ART

In the field of power electronics, semiconductor switching elements such as MOSFETs (metal oxide semiconductor field effect transistors) or IGBTs (insulated gate bipolar transistors) are used. In a circuit including these switching elements, power loss can be reduced by increasing the speed of switching operations of the elements. However, when the speed of switching operations of the elements is excessively increased, ringing occurs in current flowing at turn-on or at turn-off of the elements. Such current ringing causes noise to occur.

The present embodiment has an object to provide electronic circuitry that detects a peak value of current ringing that occurs at turn-on of a switching element.

In order to achieve the above-described object, an electronic circuitry according to the present embodiment comprises: an input terminal, a detection terminal, a diode having a cathode connected to the input terminal and an anode connected to the detection terminal, a resistor connected between the detection terminal and a first reference voltage, and a capacitor connected between the detection terminal and a second reference voltage. A voltage equal to a minimum value of a voltage applied to the input terminal is outputted from the detection terminal.

In addition, a power conversion device according to the present embodiment comprises: a power conversion circuit including two switching elements that constitute an arm pair, and two drive circuits configured to supply drive currents to the two switching elements respectively, and an electronic circuitry including an input terminal connected to a connection point between the two switching elements, a detection terminal, a diode having a cathode connected to the input terminal and an anode connected to the detection terminal, a resistor connected between the detection terminal and a first reference voltage, and a capacitor connected between the detection terminal and a second reference voltage. A voltage equal to a minimum value of a voltage applied to the input terminal is outputted from the detection terminal of the electronic circuitry.

### BRIEF DESCRIPTION OF THE DRAWINGS

FIG. 1 illustrates a configuration of a motor control system according to Embodiment 1;

FIG. 2 is an equivalent circuit at turn-on of a switching element;

FIG. 3 is a timing chart describing an operation at turn-on of a switching element;

FIG. 4 illustrates a configuration of an electronic circuitry according to Embodiment 1;

FIG. 5 shows an equivalent circuit in FIG. 4;

FIG. 6 is a timing chart describing an operation at turn-on of a switching element focusing on ringing;

FIG. 7 shows a model including a voltage source that imitates noise of a circuit;

FIG. 8 illustrates a configuration of an electronic circuitry according to Embodiment 2;

FIG. 9 illustrates a configuration of an electronic circuitry according to Embodiment 3;

FIG. 10 illustrates a configuration of an electronic circuitry according to Embodiment 4;

FIG. 11 illustrates a configuration of an electronic circuitry according to Embodiment 5; and

FIG. 12 illustrates a configuration of an electronic circuitry according to Embodiment 6.

### DETAILED DESCRIPTION

Hereinafter, embodiments will be described with reference to the drawings. The same or corresponding elements in the drawings are denoted by the same reference, and detailed description will be omitted as appropriate.

### Embodiment 1

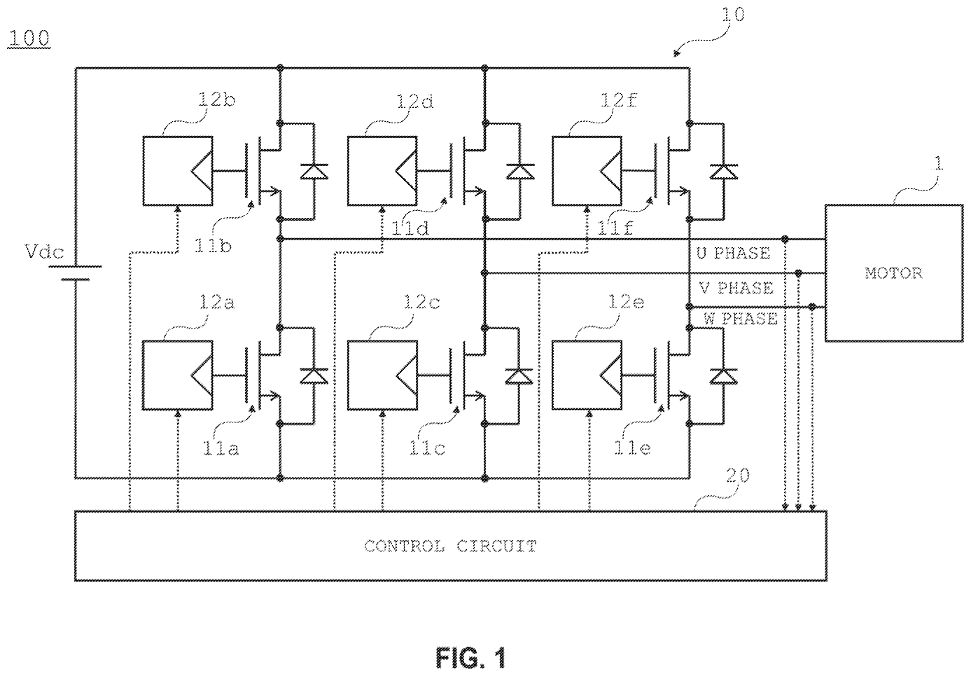

FIG. 1 illustrates a configuration of a motor control system 100 according to Embodiment 1. The motor control system 100 comprises a three-phase AC motor 1 as a load, a DC power supply Vdc, switching elements 11a to 11f constituting a three-phase inverter circuit 10, and drive circuits 12a to 12f which drive the switching elements 11a to 11f respectively.

The switching elements 11a and 11b are N-channel MOSFETs. The switching elements 11a and 11b constitute a U-phase arm pair of the inverter circuit 10. The drive circuit 12a controls a gate current (drive current) of the switching element 11a to control switching operation, i.e., turn-on and turn-off of the switching element 11a. The drive circuit 12b controls a gate current of the switching element 11b to control switching operation of the switching element 11b.

Similarly, the switching elements 11c and 11d are N-channel MOSFETs. The switching elements 11c and 11d constitute a V-phase arm pair of the inverter circuit 10. The drive circuit 12c controls a gate current of the switching element 11c to control switching operation of the switching element 11c. The drive circuit 12d controls a gate current of the switching element 11d to control switching operation of the switching element 11d.

Similarly, the switching elements 11e and 11f are N-channel MOSFETs. The switching elements 11e and 11f constitute a W-phase arm pair of the inverter circuit 10. The drive circuit 12e controls a gate current of the switching element 11e to control switching operation of the switching element 11e. The drive circuit 12f controls a gate current of the switching element 11f to control switching operation of the switching element 11f.

The motor control system 100 also comprises a control circuit 20. The control circuit 20 generates a PWM signal based on U-phase, V-phase, and W-phase currents of the motor 1, and provides waveform data of the gate currents to the drive circuits 12a to 12f of the switching elements 11a to 11f in synchronization with the PWM signal.

In particular, the control circuit 20 provides waveform data of the gate currents to the drive circuits 12a and 12b in synchronization with the PWM signal. The drive circuit 12a generates a gate current in accordance with the waveform data provided from the control circuit 20, and supplies the gate current to the switching element 11a. The drive circuit 12b generates a gate current in accordance with the waveform data provided from the control circuit 20, and supplies the gate current to the switching element 11b.

Similarly, the control circuit 20 provides waveform data of the gate currents to the drive circuits 12c and 12d in synchronization with the PWM signal. The drive circuit 12c generates a gate current in accordance with the waveform data provided from the control circuit 20, and supplies the gate current to the switching element 11c. The drive circuit 12d generates a gate current in accordance with the waveform data provided from the control circuit 20, and supplies the gate current to the switching element 11d.

Similarly, the control circuit 20 provides waveform data of the gate currents to the drive circuits 12e and 12f in synchronization with the PWM signal. The drive circuit 12e generates a gate current in accordance with the waveform data provided from the control circuit 20, and supplies the gate current to the switching element 11e. The drive circuit 12f generates a gate current in accordance with the waveform data provided from the control circuit 20, and supplies the gate current to the switching element 11f.

Herein, an operation at turn-on of the switching elements 11a to 11f in FIG. 1 will be described. The following description focuses on the switching element 11a, and an operation when the switching element 11a is turned on will be described. However, the following description also similarly holds for the other switching elements 11b to 11f.

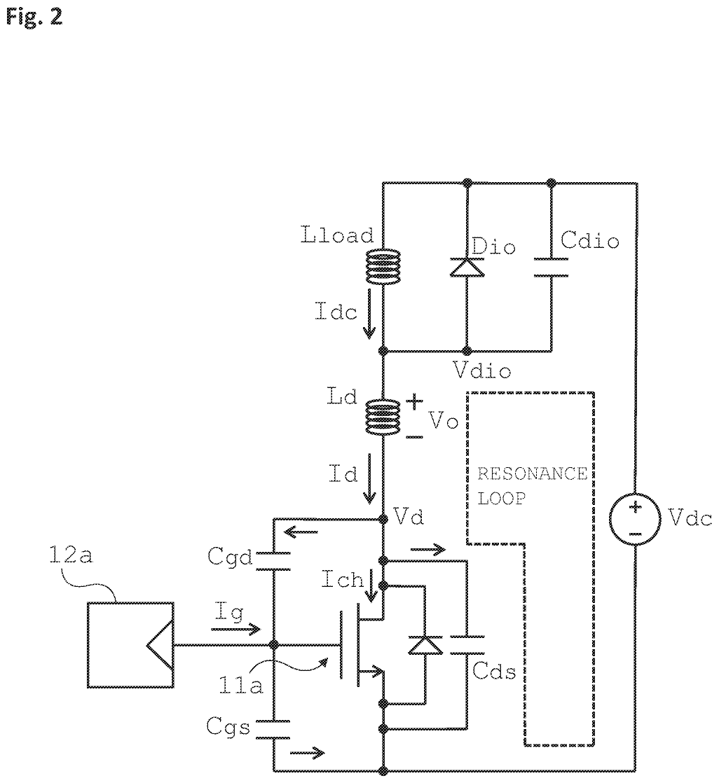

FIG. 2 is an equivalent circuit at turn-on of the switching element 11a in FIG. 1. When the switching element 11a is turned on, the switching element 11b that constitutes the U-phase arm pair together with the switching element 11a is OFF. In FIG. 2, the switching element 11b in OFF is represented by a diode Dio and a parasitic capacitor Cdio.

An inductor Lload represents inductance of the motor 1 which is a load. An inductor Ld represents parasitic inductance of a wring between the drain terminals of the switching elements 11a and 11b.

The switching element 11a has a gate-source parasitic capacitor Cgs, a gate-drain parasitic capacitor Cgd and a drain-source parasitic capacitor Cds. The drive circuit 12a supplies a gate current Ig to the gate terminal of the switching element 11a.

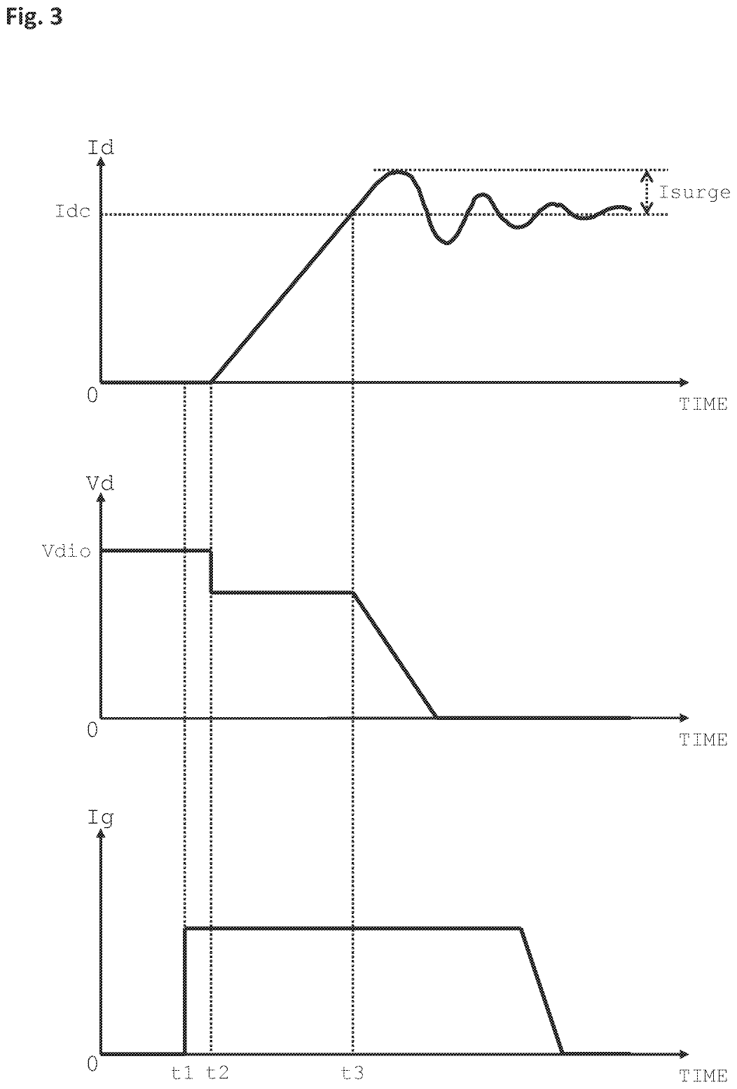

FIG. 3 is a timing chart describing an operation at turn-on of the switching element 11a. In an initial state on the left end of FIG. 3, the gate current Ig supplied from the drive circuit 12a is 0, and the gate voltage of the switching element 11a is also 0. Consequently, the switching element 11a is OFF, the drain current Id is 0, and the drain voltage Vd is equal to an anode-side voltage Vdio of the diode Dio.

At time t1, the drive circuit 12a increases the gate current Ig stepwise. This causes charging of the gate-source parasitic capacitor Cgs of the switching element 11a to be started, and the gate voltage of the switching element 11a rises.

At time t2, when the gate voltage of the switching element 11a exceeds a threshold voltage, a channel is formed, and the drain current Id starts flowing. The drain current Id increases along with the rise in gate voltage. In FIG. 3, the increase of the drain current Id is approximated by a linear function.

At this time, the diode Dio is ON, and the anode-side voltage Vdio of the diode Dio does not change and is constant. On the other hand, the flow of the drain current Id produces a voltage Vo across both terminals of the inductor Ld, and the drain voltage Vd decreases.

At time t3, when the drain current Id becomes equal to a stationary component of current flowing through the inductor Lload, i.e., the load current Idc, the diode Dio is turned off, and the anode-side voltage Vdio of the diode Dio decreases. At this time, a resonance loop as shown in FIG. 2 is formed, and ringing of the drain current Id occurs.

In Embodiment 1, in order to detect the peak value of ringing of the drain current Id at turn-on of the switching element 11a, i.e., a surge current Isurge, a voltage correlated to the surge current Isurge is detected.

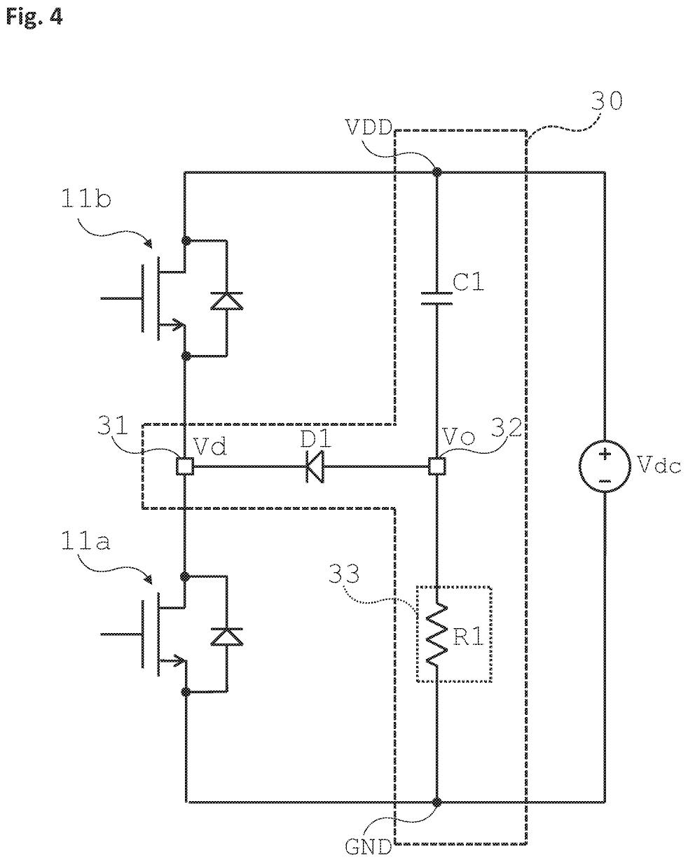

FIG. 4 illustrates a configuration of electronic circuitry 30 according to Embodiment 1. Electronic circuitry 30 comprises an input terminal 31 to which the drain voltage Vd of the switching element 11a is applied, and a detection terminal 32 from which a voltage Vo equal to a minimum value of the drain voltage Vd is outputted. Electronic circuit 30 also comprises a diode D1, a resistor 33 including a first resistance element R1, and a capacitor C1.

The cathode of the diode D1 is connected to the input terminal 31. The anode of the diode D1 is connected to the detection terminal 32. The one end of the resistor 33 is connected to the detection terminal 32. The other end of the resistor 33 is connected to a first reference voltage GND. The one end of the capacitor C1 is connected to the detection terminal 32. The other end of the capacitor C1 is connected to a second reference voltage VDD. In Embodiment 1, the first reference voltage GND=0, and the second reference voltage VDD=Vdc.

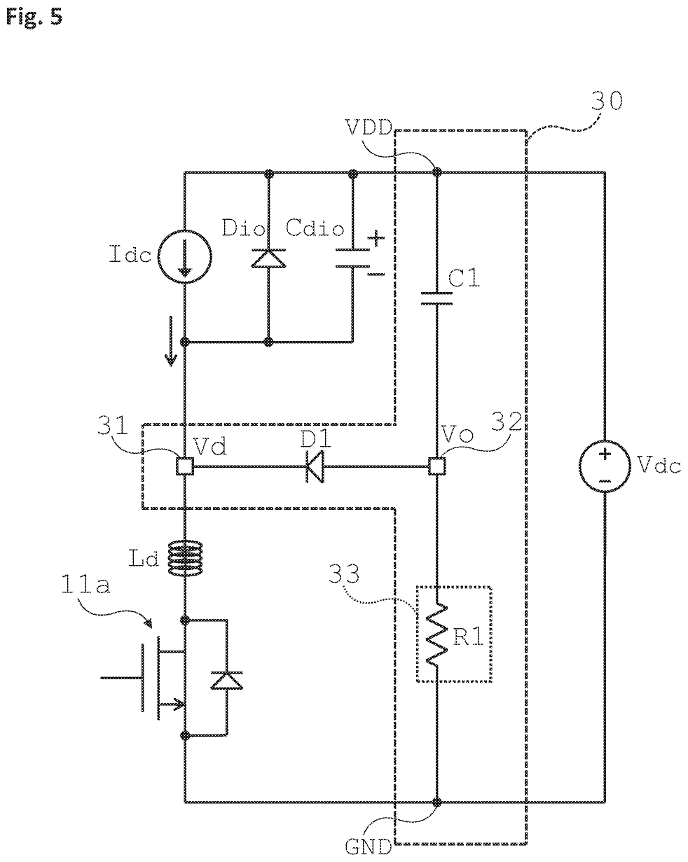

FIG. 5 is an equivalent circuit in FIG. 4. Similarly to the equivalent circuit in FIG. 3, the switching element 11b in OFF is represented by a diode Dio and a parasitic capacitor Cdio. An inductor Lload in FIG. 3 is represented by a current source Idc in FIG. 4. The current Idc is a stationary component of current flowing through the motor 1 which is a load, i.e., the current Idc is a load current.

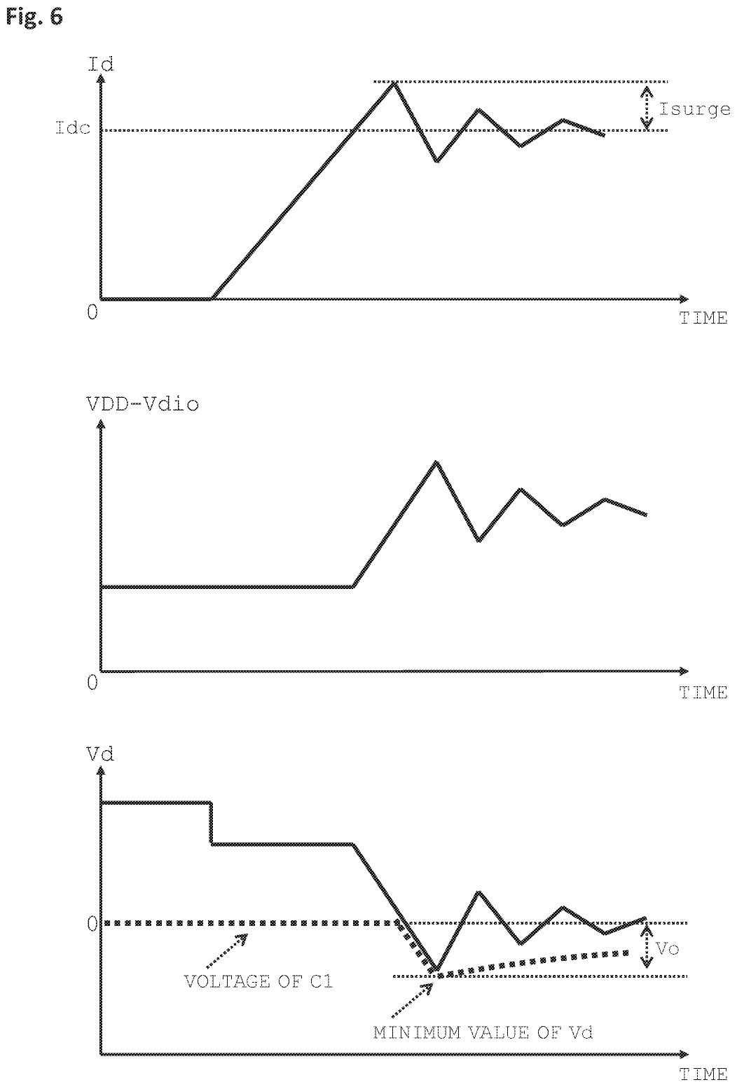

FIG. 6 is a timing chart describing an operation at turn-on of the switching element 11a focusing on ringing. In FIG. 6, each ringing waveform which is actually a continuous curve is approximated by a broken line. When current ringing occurs in the drain current Id of the switching element 11a, voltage ringing correlated to this current ringing occurs in a voltage obtained by subtracting the diode voltage Vdio from the second reference voltage VDD, i.e., VDD−Vdio. This also causes voltage ringing to occur in the drain voltage Vd correlated to VDD−Vdio (it was omitted in FIG. 3).

In FIG. 6, the ringing waveform of VDD−Vdio and the ringing waveform of the drain voltage Vd have signs opposite to each other. In other words, when the ringing waveform of VDD−Vdio rises, the ringing waveform of the drain voltage Vd drops to the negative side lower than 0.

When the drain voltage Vd drops to the negative side lower than 0, the potential at the cathode of the diode D1 becomes lower than the potential at the anode, and a forward current flows through the diode D1. The capacitor C1 is charged with the forward current to a voltage equal to the minimum value of ringing of the drain voltage Vd. When the drain voltage Vd changes to rise from the minimum value, the capacitor C1 is discharged via the resistor 33.

This discharge is performed in accordance with the time constant “C1*R1” determined by the value of the capacitor C1 and the value of the first resistance element R1 included in the resistor 33. Thus, appropriate setting of the time constant “C1*R1” enables the capacitor C1 to hold the minimum value of the drain voltage Vd for a required time period.

Summarizing the above discussions, ringing of the drain current Id and the ringing of VDD−Vdio are correlated to each other. Also, VDD−Vdio and the drain voltage Vd are negatively correlated to each other. The peak value of ringing of the drain current Id, i.e., the surge current Isurge, and the minimum value of the drain voltage Vd are therefore correlated to each other. Furthermore, the minimum value of the drain voltage Vd and the charged voltage Vo of the capacitor C1 are equal.

As a result, the peak value of ringing of the drain current Id, i.e., the surge current Isurge, and the charged voltage Vo of the capacitor C1 outputted from the detection terminal 32 are linked by a constant that can be calculated from the load current Idc and the circuit constants. The control circuit 20 always detects the load current Idc flowing through the motor 1. In addition, the circuit constants are determined at the time of design and already known. Consequently, the surge current Isurge can be detected based on the voltage Vo outputted from the detection terminal 32.

As described above, electronic circuitry 30 according to Embodiment 1 comprises the first diode D1 having the cathode connected to the input terminal 31 and the anode connected to the detection terminal 32, the resistor 33 connected between the detection terminal 32 and the first reference voltage GND, and the capacitor C1 connected between the detection terminal 32 and the second reference voltage VDD. The voltage Vo equal to the minimum value of the drain voltage Vd applied to the input terminal 31 is outputted from the detection terminal 32.

According to the above features, electronic circuitry 30 according to Embodiment 1 can detect the peak value of ringing of the drain current Id that occurs at turn-on of the switching element 11a, i.e., the surge current Isurge.

In particular, the load current Idc flowing through the motor 1 varies from 0 to the positive side in response to switching operation of the switching element 11a, while ringing of the drain voltage Vd varies from 0 to the negative side. In other words, the variation in the load current Idc and the variation in ringing of the drain voltage Vd are directed oppositely. In Embodiment 1, the surge current Isurge can therefore be detected without being affected by the variation in the load current Idc.

In Embodiment 1, the first reference voltage GND=0, and the second reference voltage VDD=Vdc. The second reference voltage VDD to which the other end of the capacitor C1 is connected is a voltage higher than the first reference voltage GND. However, the second reference voltage VDD may be a voltage identical to the first reference voltage GND. In other words, the second reference voltage VDD should only be identical to the first reference voltage GND, or higher than the first reference voltage GND.

It is preferable that opposite ends of the diode D1 be directly connected to the input terminal 31 and the detection terminal 32 respectively, without the interposition of other elements. On the other hand, the resistor 33 may include a plurality of resistance elements connected in series or in parallel, rather than including the single resistance element R1 alone.

A discharge property of the capacitor C1 is characterized by the time constant “C1*R1” which is a product of the value of the capacitor C1 and the value of the first resistance element R1. Thus, these values may be set based on requirements imposed on the discharge property of the capacitor C1. For example, the values of the capacitor C1 and the first resistance element R1 may be set based on requirements that “when the capacitor C1 charged at a rise of the gate current Ig (that rises in synchronization with the PWM signal) is discharged until the gate current Ig rises next, the charged voltage Vo should not be buried in the noise of the circuit”.

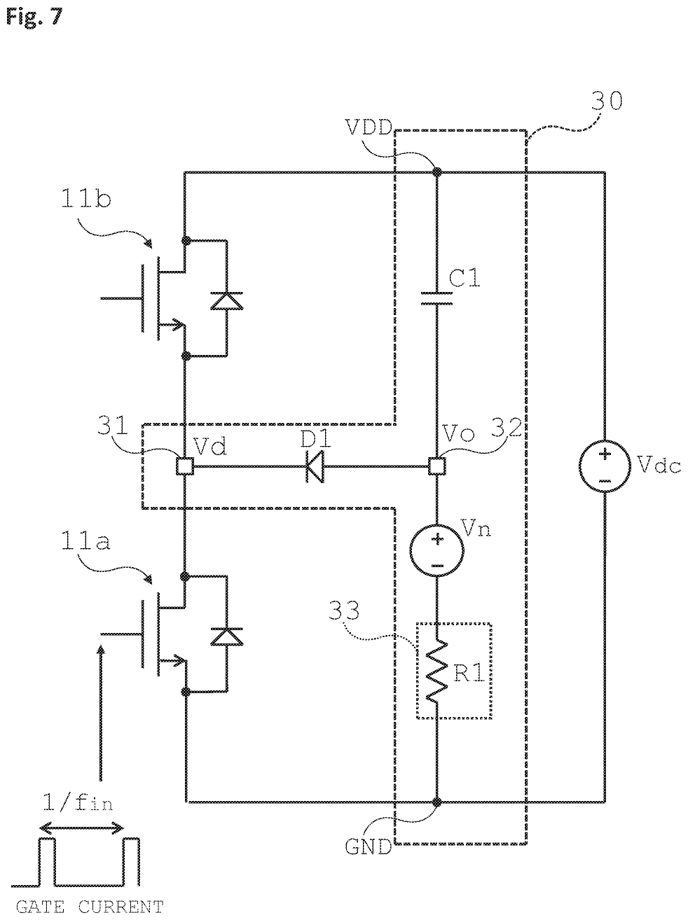

Specifically, as shown in FIG. 7, let us consider a model in which a voltage source Vn that imitates the noise of the entire circuit including electronic circuitry 30 is virtually connected between the detection terminal 32 and the resistor 33. In this case, the values of the capacitor C1 and the first resistance element R1 are set as follows:

$${V}_{n}^{2} < {( {V}_{dmin} ( 1 - {e}^{- \frac{1}{fin ( {C}_{1} {R}_{1} )}} ) )}^{2}$$

where “fin” is the frequency of the PWM signal, “Vn” is the voltage of the voltage source Vn that imitates the noise, and “Vdmin” is the minimum value of the voltage applied to the input terminal 31, i.e., the minimum value of the drain voltage Vd.

If thermal noise in the capacitor C1 and the first resistance element R1 is dominant in the noise of the entire circuit including electronic circuitry 30, the above inequation can be approximated as follows:

$$1 < \frac{{C}_{1}}{k T} {( {V}_{dmin} ( 1 - {e}^{- \frac{1}{fin ( {C}_{1} {R}_{1} )}} ) )}^{2}$$

where “T” is the ambient temperature, and “k” is the Boltzmann constant.

### Embodiment 2

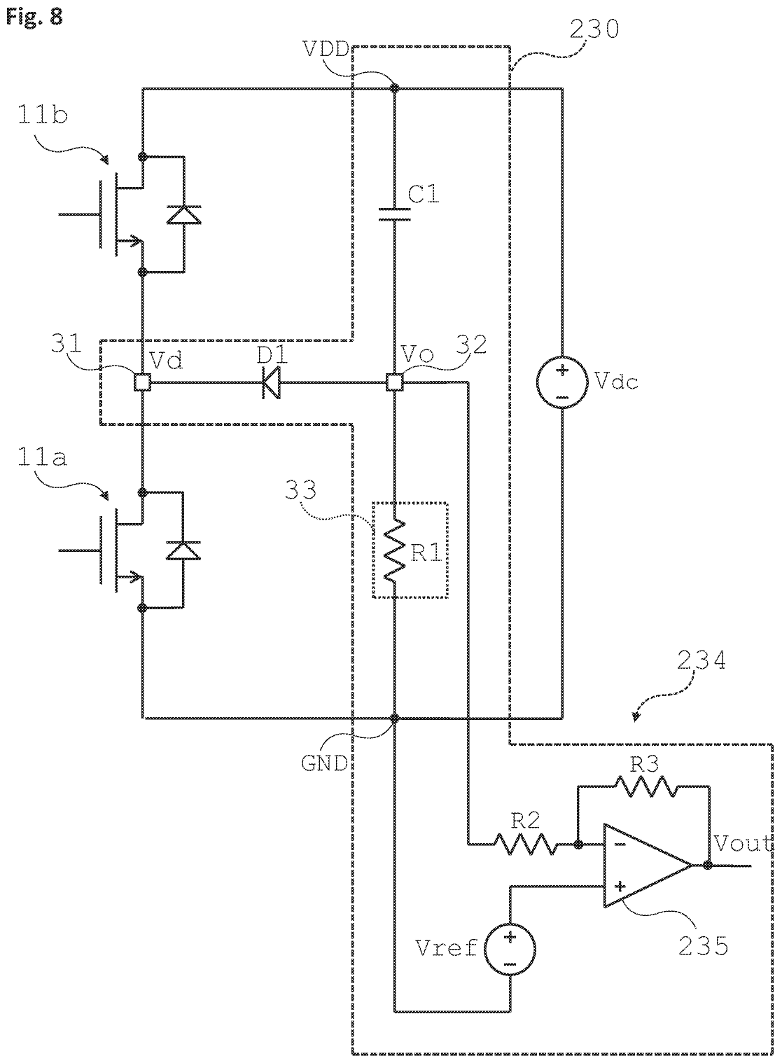

FIG. 8 illustrates a configuration of electronic circuitry 230 according to Embodiment 2. In the above-described Embodiment 1, the voltage Vo outputted from the detection terminal 32 is a voltage lower than the first reference voltage GND, and is a negative voltage when the first reference voltage GND=0. In order to address a case where this is inconvenient, electronic circuitry 230 comprises a buffer circuit 234 that inverts the voltage Vo outputted from the detection terminal 32 and shifts the inverted voltage to the positive side by a predetermined voltage Vref.

The buffer circuit 234 includes an operational amplifier (which can also be referred to as “amplifier”) 235, a second resistance element R2 connected between the negative terminal of the operational amplifier 235 and the detection terminal 32, a third resistance element R3 connected between the output terminal and the negative terminal of the operational amplifier 235, and a constant voltage source Vref connected between the positive terminal of the operational amplifier 235 and the first reference voltage GND.

The output voltage Vout of the operational amplifier 235 is expressed as follows:

$${V}_{out} = {V}_{ref} + \frac{{R}_{3}}{{R}_{2}} ( {V}_{ref} - {V}_{o} )$$

### Embodiment 3

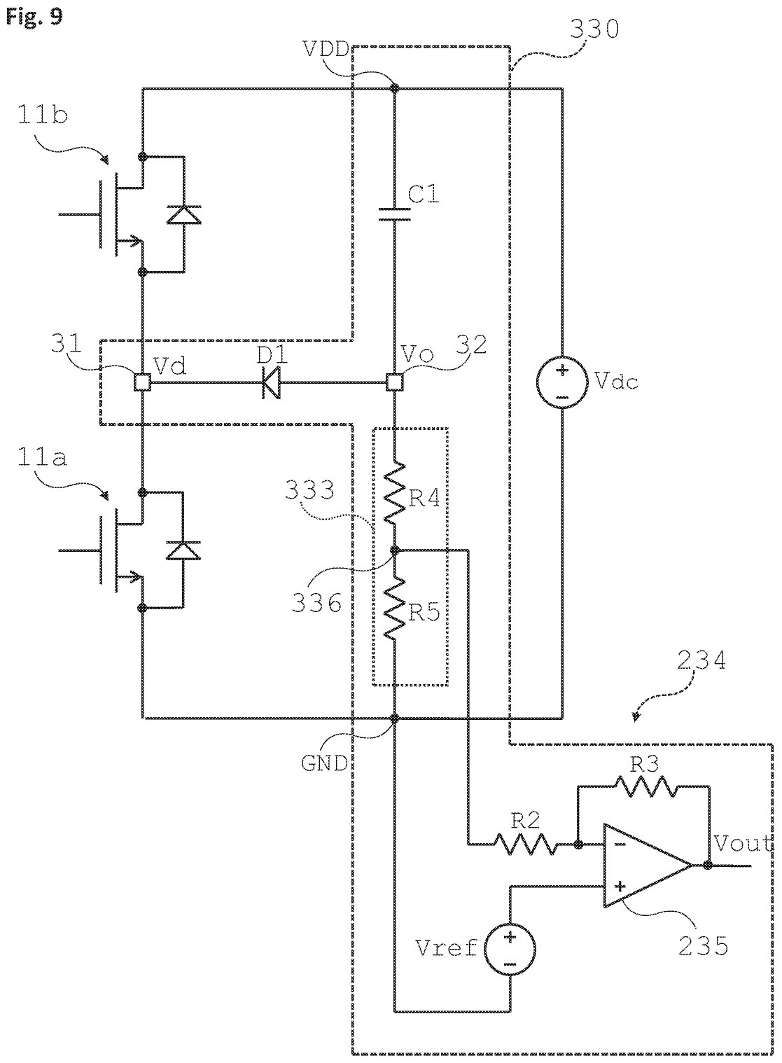

FIG. 9 illustrates a configuration of electronic circuitry 330 according to Embodiment 3. In the above-described Embodiment 2, if the range of the voltage Vo outputted from the detection terminal 32 is too wide, the output voltage Vout of the operational amplifier 235 might exceed the maximum voltage that the operational amplifier 235 can output.

To address this situation, a resistor 333 of electronic circuitry 330 includes a fourth resistance element R4 and a fifth resistance element R5 connected in series, and the negative terminal of the operational amplifier 235 is connected to a connection point 336 between the fourth resistance element R4 and the fifth resistance element R5. Consequently, the voltage Vo outputted from the detection terminal 32 is divided by the fourth resistance element R4 and the fifth resistance element R5, and the divided voltage is inputted to the negative terminal of the operational amplifier 235. Therefore, the output voltage Vout of the operational amplifier 235 can be kept at less than or equal to the maximum voltage that the operational amplifier 235 can output. Specifically, the following relation should be satisfied.

$${V}_{ref} + \frac{{R}_{3}}{{R}_{2}} ( {V}_{ref} - \frac{{R}_{5}}{{R}_{4} + {R}_{5}} {V}_{dmin} ) \leq {V}_{max}$$

where “Vdmin” is the minimum value of the voltage applied to the input terminal 31, i.e., the minimum value of the drain voltage Vd, and “Vmax” is the maximum voltage that the operational amplifier 235 can output.

### Embodiment 4

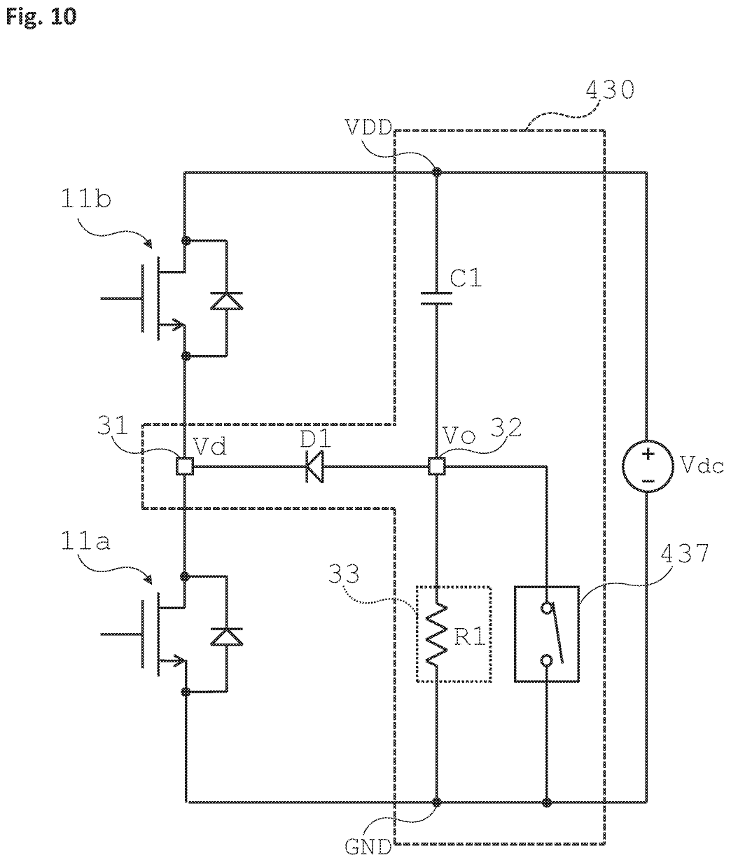

FIG. 10 illustrates a configuration of electronic circuitry 430 according to Embodiment 4. Electronic circuitry 430 comprises a reset circuit 437 that discharges the capacitor C1 to reduce the charged voltage Vo to zero. The configuration of the reset circuit 437 is not particularly limited, and as an example, is a MOS switch connected between the detection terminal 32 and the first reference voltage GND.

For example, depending on the magnitude of the time constant “C1*R1”, the capacitor C1 charged at a rise of the gate current Ig (that rises in synchronization with the PWM signal) might not be sufficiently discharged until the gate current Ig rises next. The reset circuit 437 can forcibly discharge the capacitor C1 in such a case.

### Embodiment 5

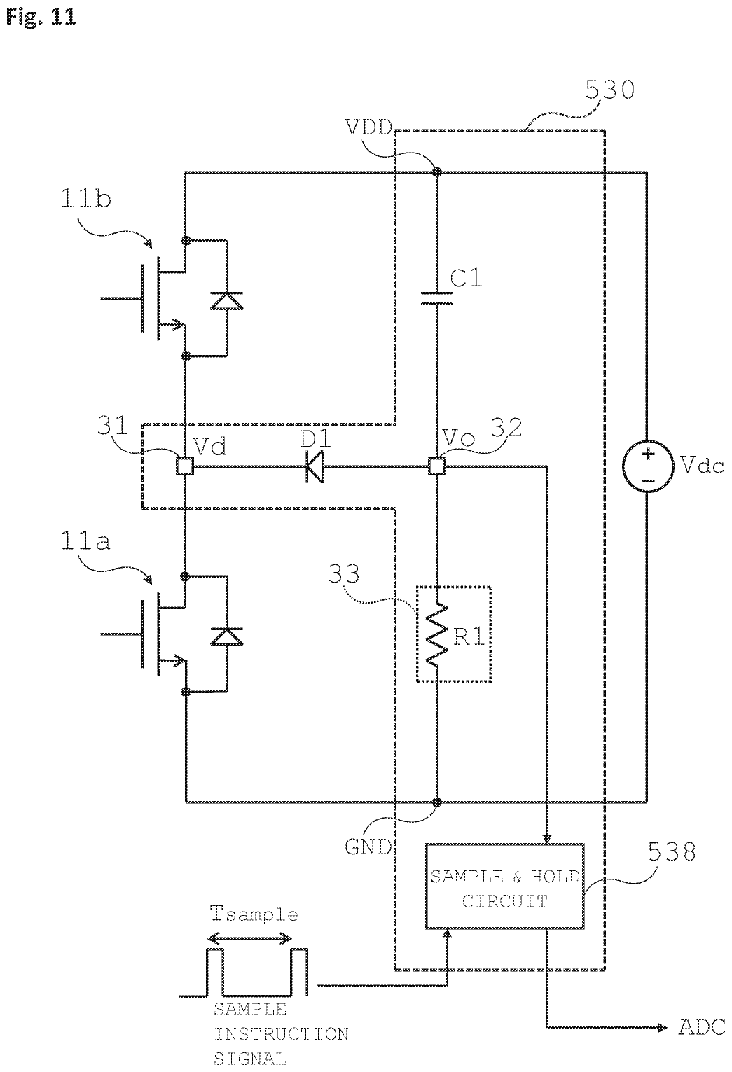

FIG. 11 illustrates a configuration of electronic circuitry 530 according to Embodiment 5. Electronic circuitry 530 comprises a sample and hold circuit 538. The sample and hold circuit 538 has an input connected to the detection terminal 32. The sample and hold circuit 538 has an output connected to an A/D converter circuit (not shown). In order not to be affected by noise, the following relation is preferably satisfied based on a discussion similar to Embodiment 1.

$${V}_{n}^{2} < {( {V}_{dmin} ( 1 - {e}^{- \frac{{T}_{sample}}{{C}_{1} {R}_{1}}} ) )}^{2}$$

where “Tsample” is a cycle of a sample instruction signal to be inputted to the sample and hold circuit 538, and “Vn” is the voltage of the voltage source Vn that imitates noise.

If thermal noise of the capacitor C1 and the first resistance element R1 is dominant in the noise of the entire circuit including electronic circuitry 530, the above relation can be approximated as follows:

$$1 < \frac{{C}_{1}}{k T} {( {V}_{dmin} ( 1 - {e}^{- \frac{{T}_{sample}}{{C}_{1} {R}_{1}}} ) )}^{2}$$

where “T” is the ambient temperature, and “k” is the Boltzmann constant.

### Embodiment 6

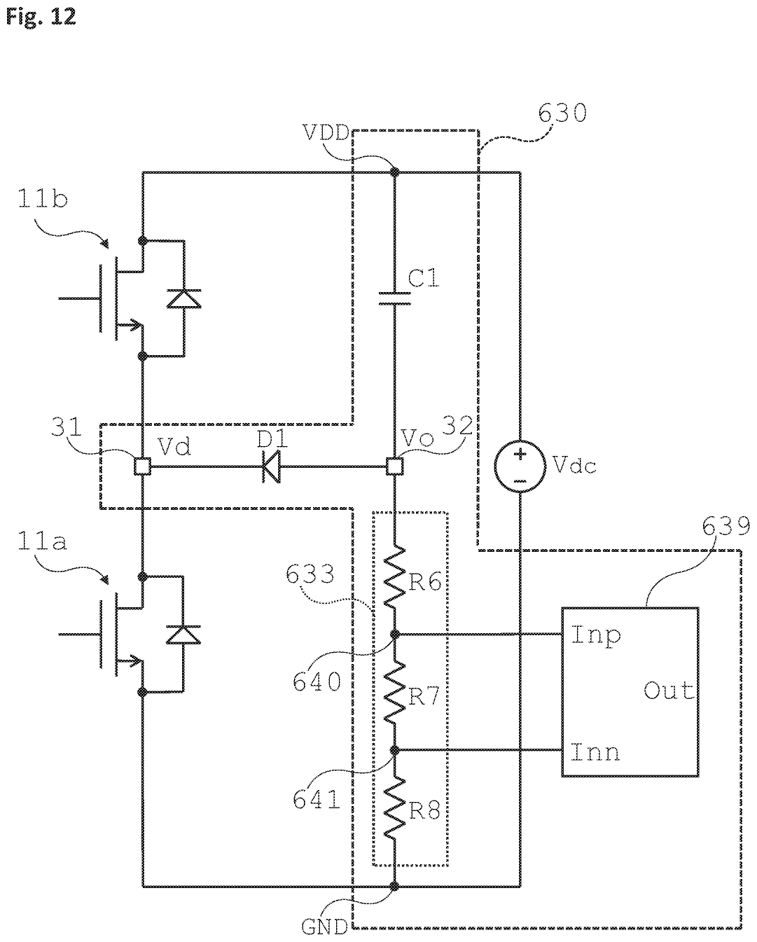

FIG. 12 illustrates a configuration of electronic circuitry 630 according to Embodiment 6. Electronic circuitry 630 comprises a differential amplifier circuit 639. A resistor 633 includes a sixth resistance element R6, a seventh resistance element R7 and an eighth resistance element R8 connected in series.

The differential amplifier circuit 639 has a positive terminal connected to a connection point 641 between the sixth resistance element R6 and the seventh resistance element R7. The differential amplifier circuit 639 has a negative terminal connected between the connection point 641 of the seventh resistance element R7 and the eighth resistance element R8. Common-mode noise can therefore be canceled out by the differential amplifier circuit 639 even if unexpectedly large noise is added to the voltage Vo outputted from the detection terminal 32.

(Modifications)

In the above-described Embodiment 1, the three-phase inverter circuit 10 is constituted by the switching elements 11a to 11f. In each pair of switching elements, the switching elements are both N-channel MOSFETs. Instead, in a case of constituting a converter circuit, for example, one of the switching elements in each pair of switching elements is an N-channel MOSFET, and the other switching element is a diode.

The switching elements 11a to 11f are not limited to MOSFETs. For example, the switching elements 11a to 11f may be IGBTs or BJTs (bipolar junction transistors). Various materials such as Si (silicon), SiC (silicon carbide), or GaN (gallium nitride) can be used as semiconductor that constitutes the switching elements 11a to 11f.

Although some embodiments have been described, these embodiments have been presented as examples. These embodiments, not intended to limit the scope of embodiments, can be embodied in other various forms, and various omissions, replacements, changes, and combinations can be carried out without departing from the spirit of the embodiments. These embodiments and their modifications are embraced in the scope and spirit of the embodiments, and are similarly embraced in claims and equivalents thereof.

Note that the present embodiment can also be configured as indicated below.

An electronic circuitry comprising:
an input terminal;
a detection terminal;
a diode having a cathode connected to the input terminal and an anode connected to the detection terminal;
a resistor connected between the detection terminal and a first reference voltage; and
a capacitor connected between the detection terminal and a second reference voltage, wherein
a voltage equal to a minimum value of a voltage applied to the input terminal is outputted from the detection terminal.

The electronic circuitry according to 1, wherein the second reference voltage is equal to the first reference voltage or higher than the first reference voltage.

The electronic circuitry according to 1 or 2, further comprising:
a first switching element connected between the input terminal and the first reference voltage; and
a second switching element connected between the input terminal and the second reference voltage, wherein
a voltage correlated to a surge current that occurs when the first switching element is turned on is outputted from the detection terminal when the second switching element is in OFF.

The electronic circuitry according to 3, wherein a following relation:

$${V}_{n}^{2} < {( {V}_{dmin} ( 1 - {e}^{- \frac{1}{fin ( {C}_{1} {R}_{1} )}} ) )}^{2}$$

is satisfied, where “R1” is a value of the resistor, “C1” is a value of the capacitor, “fin” is a frequency of a drive current supplied to the first switching element, “Vn” is a voltage of a voltage source that imitates noise virtually connected between the detection terminal and the resistor, and “Vdmin” is the minimum value of the voltage applied to the input terminal.

The electronic circuitry according to item 4, wherein the relation is approximated as follows:

$$1 < \frac{{C}_{1}}{k T} {( {V}_{dmin} ( 1 - {e}^{- \frac{1}{fin ( {C}_{1} {R}_{1} )}} ) )}^{2}$$

where “T” is ambient temperature, and “k” is Boltzmann constant.

The electronic circuitry according to any one of 1 to 5, further comprising a buffer circuit configured to invert and shift the voltage outputted from the detection terminal.

The electronic circuitry according to 6, wherein the buffer circuit includes:
an amplifier,
a second resistance element connected between a negative terminal of the amplifier and the detection terminal,
a third resistance element connected between an output terminal and the negative terminal of the amplifier, and
a constant voltage source connected between a positive terminal of the amplifier and the first reference voltage.

The electronic circuitry according to 6, wherein
the resistor includes a fourth resistance element and a fifth resistance element connected in series, and
the buffer circuit includes:
   an amplifier,
   a second resistance element connected between a negative terminal of the amplifier and a connection point between the fourth resistance element and the fifth resistance element,
   a third resistance element connected between an output terminal and the negative terminal of the amplifier, and
   a constant voltage source connected between a positive terminal of the amplifier and the first reference voltage.

The electronic circuitry according to item 8, wherein a relation:

$${V}_{ref} + \frac{{R}_{3}}{{R}_{2}} ( {V}_{ref} - \frac{{R}_{5}}{{R}_{4} + {R}_{5}} {V}_{dmin} ) \leq {V}_{max}$$

is satisfied, where “R2” is a value of the second resistance element, “R3” is a value of the third resistance element, “R4” is a value of the fourth resistance element, “R5” is a value of the fifth resistance element, “Vdmin” is a minimum value of the voltage applied to the input terminal, “Vref” is a voltage of the constant voltage source, and “Vmax” is a maximum voltage that the amplifier can output.

The electronic circuitry according to any one of 1 to 9, further comprising a reset circuit configured to discharge the capacitor.

The electronic circuitry according to 10, wherein the reset circuit is a switch connected between the detection terminal and the first reference voltage.

The electronic circuitry according to any one of 1 to 11, further comprising a sample and hold circuit configured to hold the voltage outputted from the detection terminal, wherein
a following relation:

$${V}_{n}^{2} < {( {V}_{dmin} ( 1 - {e}^{- \frac{{T}_{sample}}{{C}_{1} {R}_{1}}} ) )}^{2}$$

is satisfied, where “R1” is a value of the resistor, “C1” is a value of the capacitor, “Tsample” is a cycle of a sample instruction signal inputted to the sample and hold circuit, “Vn” is a voltage of a voltage source configured to imitate noise virtually connected between the detection terminal and the resistor, and “Vdmin” is the minimum value of the voltage applied to the input terminal.

The electronic circuitry according to 12, wherein the relation is approximated as follows:

$$1 < \frac{{C}_{1}}{k T} {( {V}_{dmin} ( 1 - {e}^{- \frac{{T}_{sample}}{{C}_{1} {R}_{1}}} ) )}^{2}$$

where “T” is ambient temperature, and “k” is Boltzmann constant.

The electronic circuitry according to any one of 1 to 13, further comprising a differential amplifier circuit, wherein
the resistor includes a sixth resistance element, a seventh resistance element and an eighth resistance element connected in series,
the differential amplifier circuit has a positive terminal connected between the sixth resistance element and the seventh resistance element, and
the differential amplifier circuit has a negative terminal connected between the seventh resistance element and the eighth resistance element.

A power conversion device comprising:
a power conversion circuit including:
   two switching elements that constitute an arm pair, and
   two drive circuits configured to supply drive currents to the two switching elements respectively; and
an electronic circuitry including:
   an input terminal connected to a connection point between the two switching elements,
   a detection terminal,
   a diode having a cathode connected to the input terminal and an anode connected to the detection terminal,
   a resistor connected between the detection terminal and a first reference voltage, and
   a capacitor connected between the detection terminal and a second reference voltage, wherein
a voltage equal to a minimum value of a voltage applied to the input terminal is outputted from the detection terminal of the electronic circuit.

The power conversion device according to 15, including three power conversion circuits, each being the power conversion circuitry.

1. An electronic circuitry comprising:
an input terminal;
a detection terminal;
a diode having a cathode connected to the input terminal and an anode connected to the detection terminal;
a resistor connected between the detection terminal and a first reference voltage; and
a capacitor connected between the detection terminal and a second reference voltage, wherein
a voltage equal to a minimum value of a voltage applied to the input terminal is outputted from the detection terminal.

2. The electronic circuitry according to claim 1, wherein the second reference voltage is equal to the first reference voltage or higher than the first reference voltage.

3. The electronic circuitry according to claim 1, further comprising:
a first switching element connected between the input terminal and the first reference voltage; and
a second switching element connected between the input terminal and the second reference voltage, wherein
a voltage correlated to a surge current that occurs when the first switching element is turned on is outputted from the detection terminal when the second switching element is in OFF.

4. The electronic circuitry according to claim 3, wherein a following relation:
$${V}_{n}^{2} < {( {V}_{dmin} ( 1 - {e}^{- \frac{1}{fin ( {C}_{1} {R}_{1} )}} ) )}^{2}$$
is satisfied, where “R1” is a value of the resistor, “C1” is a value of the capacitor, “fin” is a frequency of a drive current supplied to the first switching element, “Vn” is a voltage of a voltage source configured to imitate noise virtually connected between the detection terminal and the resistor, and “Vdmin” is the minimum value of the voltage applied to the input terminal.

5. The electronic circuitry according to claim 4, wherein the relation is approximated as follows:
$$1 < \frac{{C}_{1}}{k T} {( {V}_{dmin} ( 1 - {e}^{- \frac{1}{fin ( {C}_{1} {R}_{1} )}} ) )}^{2}$$
where “T” is ambient temperature, and “k” is Boltzmann constant.

6. The electronic circuitry according to claim 1, further comprising a buffer circuit configured to invert and shift the voltage outputted from the detection terminal.

7. The electronic circuitry according to claim 6, wherein the buffer circuit includes:
an amplifier,
a second resistance element connected between a negative terminal of the amplifier and the detection terminal,
a third resistance element connected between an output terminal and the negative terminal of the amplifier, and
a constant voltage source connected between a positive terminal of the amplifier and the first reference voltage.

8. The electronic circuitry according to claim 6, wherein
the resistor includes a fourth resistance element and a fifth resistance element connected in series, and
the buffer circuit includes:
an amplifier,
a second resistance element connected between a negative terminal of the amplifier and a connection point between the fourth resistance element and the fifth resistance element,
a third resistance element connected between an output terminal and the negative terminal of the amplifier, and
a constant voltage source connected between a positive terminal of the amplifier and the first reference voltage.

9. The electronic circuitry according to claim 8, wherein a following relation:
$${V}_{ref} + \frac{{R}_{3}}{{R}_{2}} ( {V}_{ref} - \frac{{R}_{5}}{{R}_{4} + {R}_{5}} {V}_{dmin} ) \leq {V}_{max}$$
is satisfied, where “R2” is a value of the second resistance element, “R3” is a value of the third resistance element, “R4” is a value of the fourth resistance element, “R5” is a value of the fifth resistance element, “Vdmin” is the minimum value of the voltage applied to the input terminal, “Vref” is a voltage of the constant voltage source, and “Vmax” is a maximum voltage that the amplifier can output.

10. The electronic circuitry according to claim 1, further comprising a reset circuit configured to discharge the capacitor.

11. The electronic circuitry according to claim 10, wherein the reset circuit is a switch connected between the detection terminal and the first reference voltage.

12. The electronic circuitry according to claim 1, further comprising a sample and hold circuit configured to hold the voltage outputted from the detection terminal, wherein
a following relation:
$${V}_{n}^{2} < {( {V}_{dmin} ( 1 - {e}^{- \frac{{T}_{sample}}{{C}_{1} {R}_{1}}} ) )}^{2}$$
is satisfied, where “R1” is a value of the resistor, “C1” is a value of the capacitor, “Tsample” is a cycle of a sample instruction signal inputted to the sample and hold circuit, “Vn” is a voltage of a voltage source configured to imitate noise virtually connected between the detection terminal and the resistor, and “Vdmin” is the minimum value of the voltage applied to the input terminal.

13. The electronic circuitry according to claim 12, wherein the relation is approximated as follows:
$$1 < \frac{{C}_{1}}{k T} {( {V}_{dmin} ( 1 - {e}^{- \frac{{T}_{sample}}{{{C}_{1}}_{1}}} ) )}^{2}$$
where “T” is ambient temperature, and “k” is Boltzmann constant.

14. The electronic circuitry according to claim 1, further comprising a differential amplifier circuit, wherein
the resistor includes a sixth resistance element, a seventh resistance element and an eighth resistance element connected in series,
the differential amplifier circuit has a positive terminal connected between the sixth resistance element and the seventh resistance element, and
the differential amplifier circuit has a negative terminal connected between the seventh resistance element and the eighth resistance element.

15. A power conversion device comprising:
a power conversion circuit including:
two switching elements that constitute an arm pair, and
two drive circuits configured to supply drive currents to the two switching elements respectively; and
an electronic circuitry including:
an input terminal connected to a connection point between the two switching elements,
a detection terminal,
a diode having a cathode connected to the input terminal and an anode connected to the detection terminal,
a resistor connected between the detection terminal and a first reference voltage, and
a capacitor connected between the detection terminal and a second reference voltage, wherein
a voltage equal to a minimum value of a voltage applied to the input terminal is outputted from the detection terminal of the electronic circuitry.

16. The power conversion device according to claim 15, further comprising three power conversion circuits, each being the power conversion circuit.
